(19) United States
(12) Patent Application Publication
(10) Pub. No.: US 2024/0243199 A1
(43) Pub. Date: Jul. 18, 2024

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: MASATO NOBORIO, Nisshin-shi (JP)

(21) Appl. No.: 18/524,036

(22) Filed: Nov. 30, 2023

(30) Foreign Application Priority Data
Jan. 13, 2023 (JP) 2023-003853

(51) Int. Cl. H01L 29/78; H01L 29/423; H01L 29/739

(52) U.S. Cl. CPC H01L 29/7813; H01L 29/4236; H01L 29/7397

(57) ABSTRACT

A first impurity region and a second impurity region are alternately formed along a longitudinal direction of a first trench. The second impurity region has: a first contact side in contact with the first trench; and a second contact side in contact with a second trench adjacent to the first trench. A first linear portion is defined to extend from a boundary of the first contact side toward the second trench, and a second linear portion is defined to extend from a boundary of the second contact side toward the first trench. A first angle between the first trench and the first linear portion connected to the first contact side is less than 90° and a second angle between the second trench and the second linear portion connected to the second contact side is less than 90° .

### CROSS REFERENCE TO RELATED APPLICATION

This application is based on Japanese Patent Application No. 2023-003853 filed on Jan. 13, 2023, the disclosure of which is incorporated herein by reference.

### TECHNICAL FIELD

The present disclosure relates to a semiconductor device having a trench gate structure.

### BACKGROUND

A semiconductor device has a trench gate structure. Specifically, the semiconductor device has a semiconductor substrate including an n⁻-type drift layer, and a base layer is formed on the drift layer. The semiconductor substrate has trenches penetrating the base layer and having a longitudinal direction which is one direction in a plane direction of the semiconductor substrate. In each of the trenches, a gate insulating film is formed to cover the wall surface, and a gate electrode is formed on the gate insulating film.

### SUMMARY

According to an aspect of the present disclosure, a semiconductor device includes a drift layer of a first conductivity type, a base layer of a second conductivity type disposed on the drift layer, and an impurity layer of the first conductivity type or the second conductivity type formed opposite to the base layer with the drift layer interposed therebetween. The semiconductor device has trench gate structures each including a gate insulating film formed on a wall surface of a trench penetrating through the base layer and a gate electrode formed on the gate insulating film. The trench extends in a longitudinal direction intersecting a stacking direction of the drift layer and the base layer. A first impurity region of the first conductivity type is formed in a surface layer portion of the base layer and has an impurity concentration higher than that of the drift layer. A second impurity region of the second conductivity type is formed in a surface layer portion of the base layer and has an impurity concentration higher than that of the base layer. A first electrode is electrically connected to the first impurity region and the second impurity region. A second electrode is electrically connected to the impurity layer. In the semiconductor device, the first impurity region and the second impurity region are alternately formed along the longitudinal direction of the trench. The second impurity region has, when viewed in the stacking direction of the drift layer and the base layer, a first contact side in contact with a first trench, and a second contact side in contact with a second trench, in a direction intersecting the longitudinal direction. The first contact side has a predetermined length and two boundaries. The second contact side has a predetermined length and two boundaries. A first linear portion is defined to extend from one of the boundaries of the first contact side toward the second trench. A second linear portion is defined to extend from the other of the boundaries of the first contact side toward the second trench. A third linear portion is defined to extend from one of the boundaries of the second contact side toward the first trench. A fourth linear portion is defined to extend from the other of the boundaries of the second contact side toward the first trench. One of a first angle between the first trench and the first linear portion and a second angle between the first trench and the second linear portion is less than 90° and the other angle is less than or equal to 90°. One of a third angle between the second trench and the third linear portion and a fourth angle between the second trench and the fourth linear portion is less than 90° and the other angle is less than or equal to 90°.

### BRIEF DESCRIPTION OF DRAWING

FIG. 1 is a cross-sectional view of a semiconductor device according to a first embodiment.

FIG. 2 is a plan view illustrating a positional relationship between a source region and a contact region.

FIG. 3 is a plan view for explaining a shape of the contact region.

FIG. 4 is a view for explaining a state in which a trench is shifted in a second direction.

FIG. 5 is a plan view for explaining a shape of a contact region in a modification of the first embodiment.

FIG. 6 is a plan view for explaining a shape of a contact region in a modification of the first embodiment.

FIG. 7 is a plan view for explaining a shape of a contact region in a modification of the first embodiment.

FIG. 8 is a plan view for explaining a shape of a contact region according to a second embodiment.

FIG. 9A is an enlarged schematic view in which a trench is shifted in an area IXA of FIG. 8.

FIG. 9B is an enlarged schematic view in which a trench is shifted in an area IXB of FIG. 8.

FIG. 10 is a plan view for explaining a shape of a contact region in a modification of the second embodiment.

### DETAILED DESCRIPTION

Conventionally, a semiconductor device having a trench gate structure has been proposed. Specifically, the semiconductor device has a semiconductor substrate constituting an n⁻-type drift layer, and a base layer is formed on the drift layer. The semiconductor substrate has trenches penetrating the base layer and having a longitudinal direction which is one direction in a plane direction of the semiconductor substrate. In each of the trenches, a gate insulating film is formed to cover the wall surface, and a gate electrode is formed on the gate insulating film.

An n⁺-type source region and a p⁺-type contact region are formed in a surface layer portion of the base layer so as to be in contact with the trench. That is, the source regions and the contact regions are alternately formed along the longitudinal direction of the trench. Each of the source region and the contact region has a rectangular planar shape.

A first electrode connected to the source region and the contact region is disposed on one side of the semiconductor substrate, and a second electrode connected to the drain layer is disposed on the other side of the semiconductor substrate.

In such a semiconductor device, when a voltage equal to or higher than a predetermined threshold voltage is applied to the gate electrode, an inversion layer is formed in a portion of the base layer in contact with the trench. The semiconductor device is turned on when a current flows from the first electrode to the drain layer through the source region and the inversion layer.

In the semiconductor device, the contact region in contact with the trench does not serve as a current path, so that the on-resistance is likely to increase. Therefore, in the above-described semiconductor device, for example, it is conceivable to shorten the length of the contact region along the longitudinal direction of the trench. However, when the length of the contact region along the longitudinal direction of the trench is reduced, the connection area between the contact region and the first electrode is reduced. Therefore, in this configuration, the contact resistance increases. When the semiconductor substrate is made of silicon carbide, the resistance of the contact region is increased, and thus the influence of the increase in contact resistance is likely to be increased.

The present disclosure provides a semiconductor device so as to suppress an increase in contact resistance between a contact region and a first electrode while suppressing an increase in on-resistance.

According to an aspect of the present disclosure, a semiconductor device includes a drift layer of a first conductivity type, a base layer of a second conductivity type disposed on the drift layer, and an impurity layer of the first conductivity type or the second conductivity type formed opposite to the base layer with the drift layer interposed therebetween. The semiconductor device has a trench gate structure including a gate insulating film formed on a wall surface of a trench penetrating through the base layer and a gate electrode formed on the gate insulating film. The trench extends in a longitudinal direction intersecting a stacking direction of the drift layer and the base layer. A first impurity region of the first conductivity type is formed in a surface layer portion of the base layer and has an impurity concentration higher than that of the drift layer. A second impurity region of the second conductivity type is formed in a surface layer portion of the base layer and has an impurity concentration higher than that of the base layer. A first electrode is electrically connected to the first impurity region and the second impurity region. A second electrode is electrically connected to the impurity layer. In the semiconductor device, the first impurity region and the second impurity region are alternately formed along the longitudinal direction of the trench. The second impurity region includes, when viewed in the stacking direction of the drift layer and the base layer, a first contact side in contact with a first trench, and a second contact side in contact with a second trench, in a direction intersecting the longitudinal direction. The first contact side has a predetermined length and two boundaries. The second contact side has a predetermined length and two boundaries. A first linear portion is defined to extend from one of the boundaries of the first contact side toward the second trench. A second linear portion is defined to extend from the other of the boundaries of the first contact side toward the second trench. A third linear portion is defined to extend from one of the boundaries of the second contact side toward the first trench. A fourth linear portion is defined to extend from the other of the boundaries of the second contact side toward the first trench. One of a first angle between the first trench and the first linear portion and a second angle between the first trench and the second linear portion is less than 90° and the other angle is less than or equal to 90°. One of a third angle between the second trench and the third linear portion and a fourth angle between the second trench and the fourth linear portion is less than 90°, and the other angle is less than or equal to 90°.

Accordingly, the area of the second impurity region can be increased, when viewed in the stacking direction of the drain layer and the base layer, without increasing the length of the second impurity region, as compared with a case where each of the first to fourth angles, in the second impurity region, is 90° (that is, the second impurity region has a rectangular planar shape). In other words, when the length of the second impurity region is reduced as compared with the case where each of the first to fourth angles is 90°, the on-resistance can be reduced while the area of the second impurity region is easily ensured. Therefore, in this semiconductor device, it is possible to suppress an increase in contact resistance while suppressing an increase in on-resistance.

Embodiments of the present disclosure will be described hereinafter with reference to the drawings. In the following description, the same or equivalent parts are denoted by the same reference numerals throughout the embodiments.

### First Embodiment

A first embodiment will be described with reference to the drawings. A semiconductor device of the present embodiment is preferably used as, for example, a power switching element in an inverter or the like.

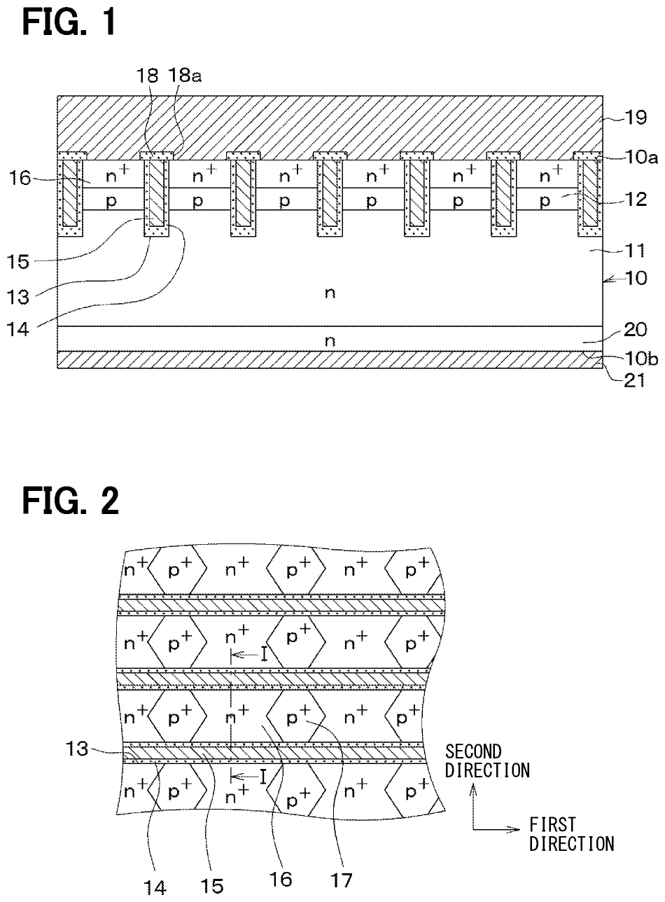

As shown in FIG. 1, the semiconductor device includes a semiconductor substrate 10. The semiconductor substrate 10 is configured by a silicon substrate, a silicon carbide substrate, a gallium nitride substrate, or the like. The semiconductor substrate 10 has an n-type drift layer 11, and a p-type base layer 12 having a relatively low impurity concentration and arranged on the drift layer 11. In the following, the semiconductor substrate 10 has one surface 10a adjacent to the base layer 12, and the other surface 10b adjacent to the drift layer 11.

Multiple trenches 13 are formed in the semiconductor substrate 10 so as to penetrate the base layer 12 from the one surface 10a and reach the drift layer 11. The base layer 12 is separated into multiple portions by the trenches 13. In the present embodiment, the trenches 13 are formed at regular intervals in a stripe manner and extend along a longitudinal direction which is a surface direction of the one surface 10a of the semiconductor substrate 10 (that is, a paper depth direction in FIG. 1).

Each of the trenches 13 is filled with a gate insulating film 14 formed so as to cover a wall surface of each of the trenches 13, and a gate electrode 15 made of polysilicon or the like formed on the gate insulating film 14. As a result, a trench gate structure is formed.

As shown in FIGS. 1 and 2, an n⁺-type source region 16 and a p⁺-type contact region 17 are formed in a surface layer portion of the base layer 12. Specifically, the source region 16 is configured to have an impurity concentration higher than that of the drift layer 11, and the contact region 17 is configured to have an impurity concentration higher than that of the base layer 12. In the present embodiment, the source regions 16 and the contact regions 17 are alternately formed along the longitudinal direction of the trench 13 (along a first direction in FIG. 2). The specific shape of the contact region 17 will be described later. In the present embodiment, the source region 16 corresponds to a first impurity region, and the contact region 17 corresponds to a second impurity region.

As shown in FIG. 1, an interlayer insulating film 18 made of boron phosphorus silicon glass (BPSG) or the like is formed on the one surface 10a of the semiconductor substrate 10. The interlayer insulating film 18 has a contact hole 18a exposing the source region 16 and the contact region 17. An upper electrode 19 is formed on the interlayer insulating film 18. The upper electrode 19 is electrically connected to the source region 16 and the contact region 17 through the contact hole 18a. In the present embodiment, the upper electrode 19 corresponds to a first electrode. FIG. 1 corresponds to a cross section taken along line I-I in FIG. 2. FIG. 2 is a plan view of the one surface 10a of the semiconductor substrate 10 and is not a cross-sectional view, but the gate insulating film 14 and the gate electrode 15 to be described later are hatched for easy understanding.

A drain layer 20 is formed on the drift layer 11 opposite to the base layer 12 (that is, the other surface 10b of the semiconductor substrate 10). A lower electrode 21 is electrically connected to the drain layer 20, and is formed on the opposite side of the drift layer 11 across the drain layer 20. Namely, the lower electrode 21 is formed on the other surface 10b of the semiconductor substrate 10, and is electrically connected to the drain layer 20. In the present embodiment, the drain layer corresponds to an impurity layer, and the lower electrode 21 corresponds to a second electrode.

The structure of the semiconductor device according to the present embodiment is described above. In the present embodiment, n-type and n⁺-type correspond to a first conductivity type, and p-type and p⁺-type correspond to a second conductivity type. In such a semiconductor device, as described above, the semiconductor substrate 10 includes the drain layer 20, the drift layer 11, the base layer 12, the source region 16, and the contact region 17.

In such a semiconductor device, when a voltage equal to or higher than a predetermined threshold voltage is applied to the gate electrode 15, an inversion layer is formed in a portion of the base layer 12 in contact with the trench 13. The semiconductor device is turned on when a current flows from the upper electrode 19 to the drain layer 20 through the source region 16 and the inversion layer. The contact region 17 in contact with the trench 13 does not serve as a current path. Therefore, as the contact region 17 in contact with the trench 13 becomes larger, the on-resistance is more likely to increase.

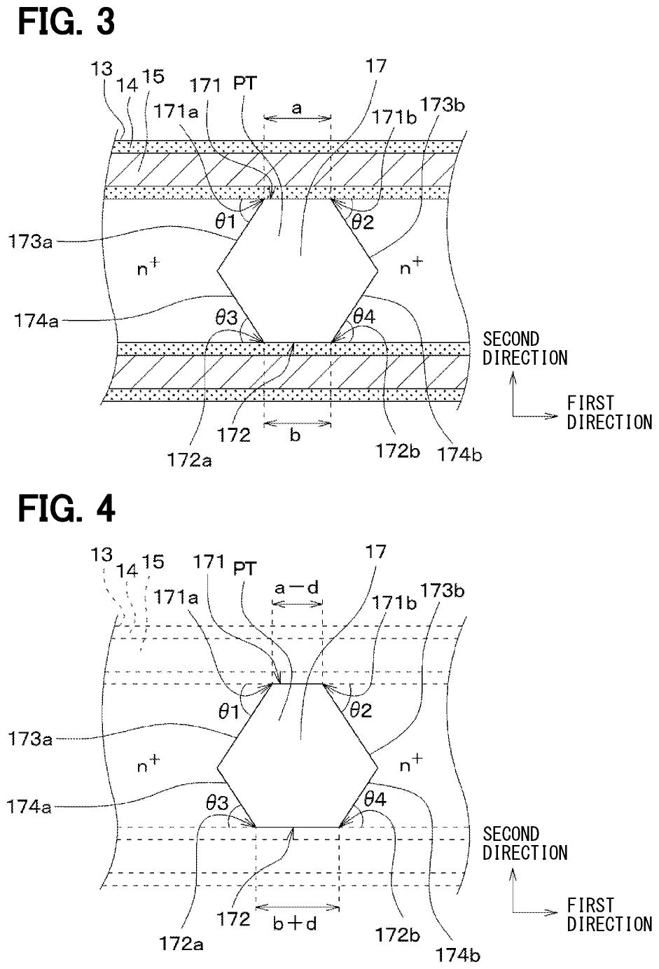

Next, the shape of the contact region 17 in the present embodiment will be specifically described with reference to FIGS. 2 and 3. FIG. 3 is an enlarged view of the vicinity of the contact region 17 shown in FIG. 2. In the following description, as shown in FIGS. 2 and 3, the longitudinal direction of the trench 13 is referred to as a first direction, and a lateral direction orthogonal to the first direction and along the surface direction of the semiconductor substrate 10 is referred to as a second direction. In FIGS. 2 and 3, the left-right direction on the paper surface is the first direction, and the up-down direction on the paper surface is the second direction.

The contact region 17 is formed between the adjacent trenches 13 in the second direction, as viewed in a normal direction with respect to the one surface 10a of the semiconductor substrate 10. The normal direction can also be referred to as a stacking direction of the drift layer 11 and the base layer 12. Further, an arrangement viewed in a direction perpendicular to the one surface 10a of the semiconductor substrate 10 maybe simply referred to as viewed in the normal direction.

The contact region 17 has a first contact side 171 in contact with a first trench 13 and a second contact side 172 in contact with a second trench adjacent to the first trench 13. Hereinafter, an area of the contact region 17 in contact with the first trench 13 in the second direction is referred to the first contact side 171. Similarly, an area of the contact region 17 in contact with the second trench 13 is referred to the second contact side 172. In FIG. 3, of the two trenches 13 arranged in the second direction, the trench 13 on the upper side of FIG. 3 is the first trench 13, and the trench 13 on the lower side of FIG. 3 is the second trench 13.

The first contact side 171 is in contact the first trench 13 with a first contact length “a” greater than 0. Similarly, the second contact side 172 is in contact with the second trench 13 with a second contact length “b” greater than 0. Therefore, the contact region 17 is shaped to have a first boundary 171a and a first boundary 171b where the contact region 17 extends away from the trench, at both ends of the first contact side 171. The contact region 17 is shaped to have a second boundary 172a and a second boundary 172b where the contact region 17 extends away from the trench, at both ends of the second contact side 172. That is, the contact region 17 is shaped to have a portion in contact with the trench 13 not in a dot shape but in a linear shape, as viewed in the normal direction.

The contact region 17 has a first linear portion 173a which is an outline from the first boundary 171a toward the second trench 13. The contact region 17 has a second linear portion 173b which is an outline from the first boundary 171b toward the second trench 13. The contact region 17 has a third linear portion 173a which is an outline from the second boundary 172a toward the first trench 13. The contact region 17 has a fourth linear portion 173b which is an outline from the second boundary 172b toward the first trench 13. The contact region 17 of the present embodiment has the first angle θ1 between the first linear portion 173a and the first trench 13, when viewed in the normal direction, the second angle θ2 between the second linear portion 173b and the first trench 13, the third angle θ3 between the third linear portion 173a and the second trench 13, and the fourth angle θ4 between the fourth linear portion 173b and the second trench 13. The first to fourth angles θ1 to θ4 are acute angles less than 90°. Further, the contact region 17 of the present embodiment has a hexagonal shape in which the first to fourth angles θ1 to θ4 are equal to each other. Note that the outline is a line forming the planar shape of the contact region 17, and can also be referred to as a boundary line relative to the source region 16, as viewed in the normal direction.

According to the present embodiment, the first to fourth angles θ1 to θ4 are less than 90°. Therefore, as compared with a case where each of the first to fourth angles θ1 to θ4 is 90° (that is, the contact region 17 has a rectangular planar shape), the area of the contact region 17, when viewed in the normal direction, can be increased without increasing the first contact length “a” and the second contact length “b”. In other words, as compared with the case where the first to fourth angles θ1 to θ4 are set to 90°, if the first contact length “a” and the second contact length “b” are shortened, it is possible to reduce the on-resistance while easily securing the area of the contact region 17. Therefore, in the semiconductor device of the present embodiment, it is possible to suppress an increase in the contact resistance while suppressing an increase in the on-resistance.

(1) In the present embodiment, the first to fourth angles θ1 to θ4 are the same angle. Therefore, as shown in FIG. 4, if the trench 13 is displaced in the second direction toward the first trench 13 due to a manufacturing error or the like, the first contact length is “a−d” and the second contact length is “b+d”, where “d” is the amount of change in the contact length due to the displacement of the trench 13. However, the sum of the first contact length and the second contact length does not change from “a+b” even if the trench 13 is displaced in the second direction. Therefore, according to the semiconductor device of the present embodiment, even if the trench 13 is displaced in the second direction due to a manufacturing error or the like, a change in the on-resistance can be suppressed, and a change in the characteristics can be suppressed.

(2) In the present embodiment, the first to fourth angles θ1 to θ4 are the same angle. Therefore, as compared with a case where the first to fourth angles θ1 to θ4 have different values, the visual inspection in the contact region 17 can be easily performed.

### Modification of First Embodiment

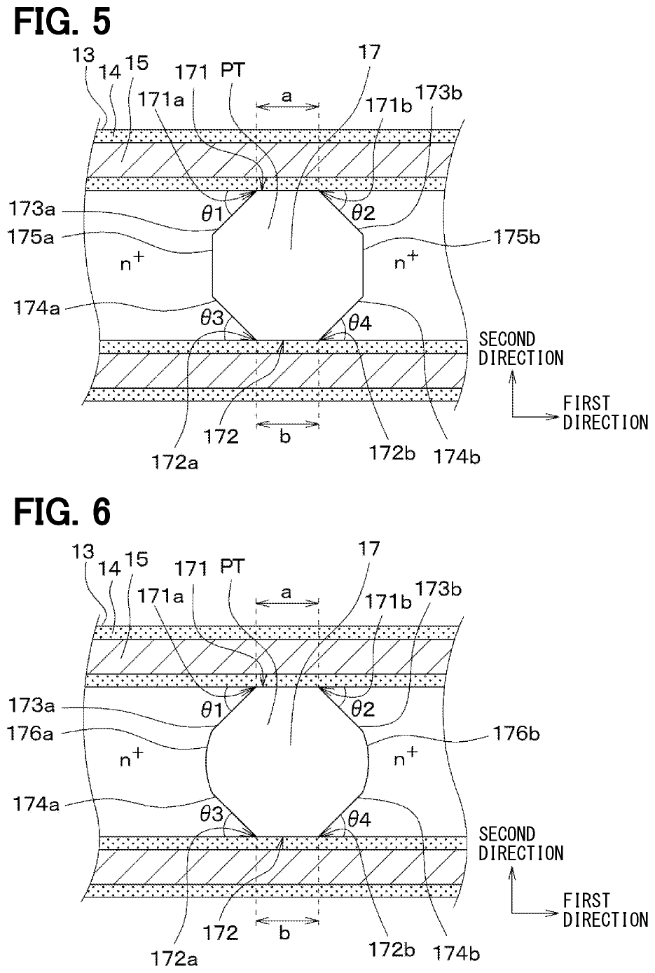

In a modification of the first embodiment, the contact region 17 may have a shape including linear portions 175a and 175b that are not parallel to the linear portion 173a, 173b, 173a, 173b. For example, as illustrated in FIG. 5, the contact region 17 may have an octagonal planar shape. That is, the linear portion 173a connected to the first contact side 171 and the linear portion 173a connected to the second contact side 172 are connected by the linear portion 175a. The linear portion 173b connected to the first contact side 171 and the linear portion 173b connected to the second contact side 172 are connected by the linear portion 175b. Accordingly, the angle of the corner of the contact region 17, when viewed in the normal direction, is larger than that in the first embodiment. The contact region 17 is formed by, for example, arranging a mask on the one surface 10a of the semiconductor substrate 10 and ion-implanting a p-type impurity. In this case, as compared with the first embodiment, the angle of the corner of the contact region 17 is increased, so that the planar shape of the contact region 17 is less likely to collapse when the contact region 17 is formed. Therefore, a change in contact resistance can be easily suppressed.

Although the planar shape of the contact region 17 is an octagonal shape in this modification, the planar shape of the contact region 17 maybe, for example, a decagonal shape or a dodecagonal shape.

Further, in a modification of the first embodiment, as shown in FIG. 6, the linear portion 173a connected to the first contact side 171 and the linear portion 173aconnected to the second contact side 172 are connected by an arc-shaped portion 176a. The linear portion 173b connected to the first contact side 171 and the linear portion 173b connected to the second contact side 172 are connected by an arc-shaped portion 176b. Further, although not particularly illustrated, for example, the linear portion 173a connected to the first contact side 171 and the linear portion 173aconnected to the second contact side 172 may be connected by the linear portion 175a. The linear portion 173b connected to the first contact side 171 and the linear portion 173b connected to the second contact side 172 may be connected by the arc-shaped portion 176b. That is, the shape between the linear portion 173a connected to the first contact side 171 and the linear portion 173a connected to the second contact side 172 and the shape between the linear portion 173b connected to the first contact side 171 and the linear portion 173b connected to the second contact side 172 can be appropriately changed.

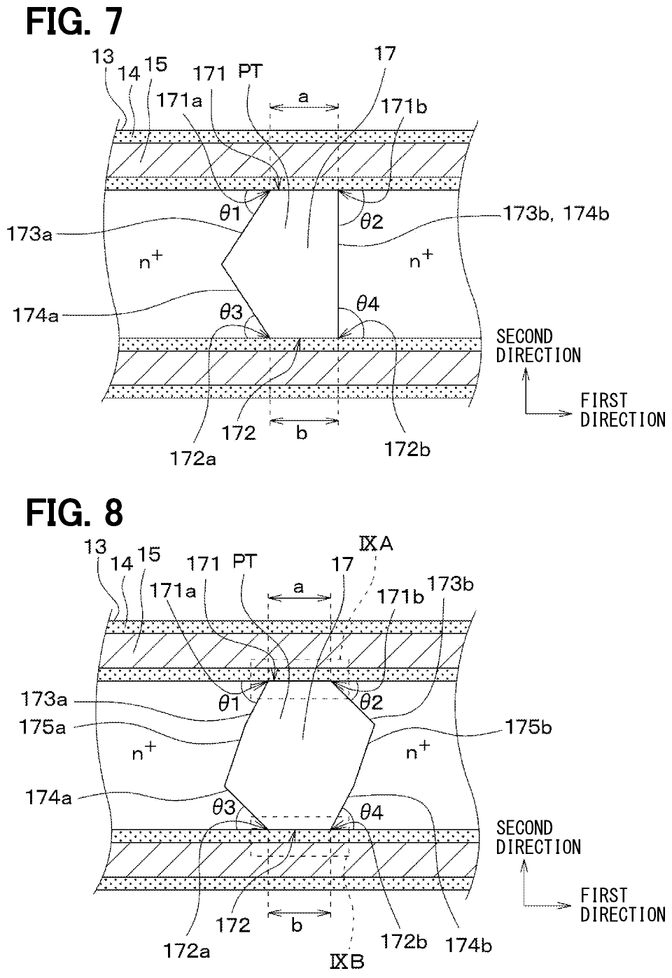

In the first embodiment, one of the first angle θ1 and the second angle θ2 maybe 90° or less, and one of the third angle θ3 and the fourth angle θ4 maybe 90° or less. For example, as shown in FIG. 7, each of the second angle θ2 and the fourth angle θ4 is 90°, in a manner that the linear portion 173b connected to the first contact side 171 and the linear portion 173b connected to the second contact side 172 is formed by a common linear portion. Even in such a contact region 17, the area of the contact region 17 can be increased as compared with the case where all of the first to fourth angles θ1 to θ4 are 90°. Thus, the same effect as that of the first embodiment can be obtained.

### Second Embodiment

A second embodiment will be described. The present embodiment is different from the first embodiment in the planar shape of the contact region 17. The remaining configurations are similar to those of the first embodiment and will thus not be described repeatedly.

In the contact region 17 of the present embodiment, as shown in FIG. 8, the first to fourth angles θ1 to θ4 are not all the same. However, the first to fourth angles θ1 to θ4 are formed to satisfy the following Formula 1 so that the sum of the first contact length and the second contact length does not change even if the trench 13 is shifted in the second direction.

1/tan θ1+1/tan θ2=1/tan θ3+1/tan θ4 (Formula 1)

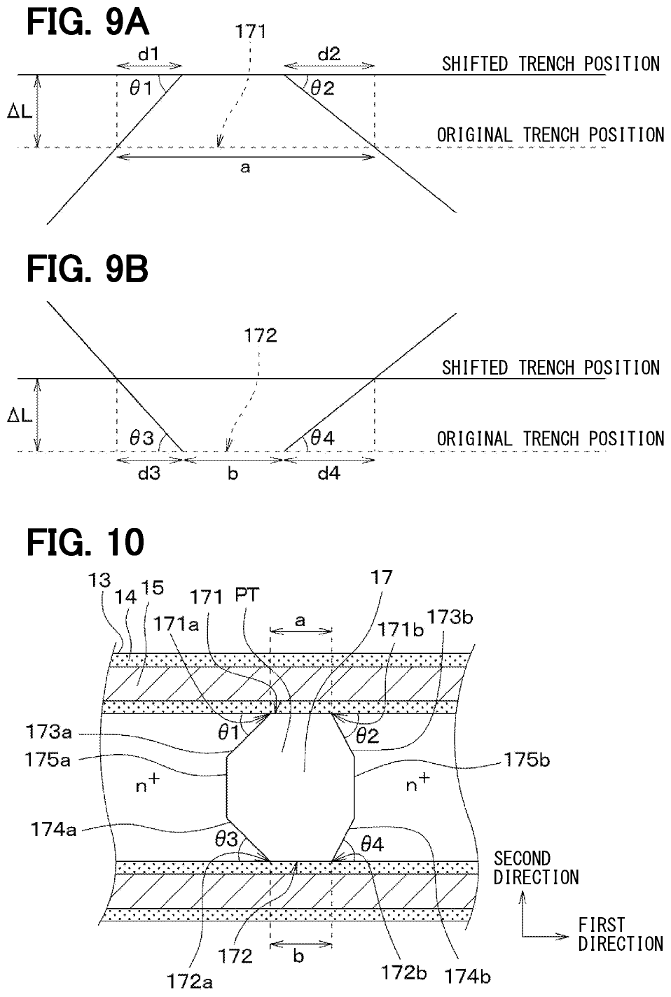

The reason for Formula 1 will be described with reference to FIGS. 9A and 9B. In a case where the trench 13 is shifted toward the first trench 13 (that is, the upper side in the drawing), when the shift amount of the trench 13 is defined as ΔL and the change amount of the first contact length due to the shift of the trench 13 is defined as d1, d2, the following Formula 2 and Formula 3 are established, regarding the first contact side 171.

ΔL/d1=tan θ1 (Formula 2)

ΔL/d2=tan θ2 (Formula 3)

Therefore, the total change amount of the first contact length is represented by the following Formula 4.

d1+d2=ΔL/tan θ1+ΔL/tan θ2 (Formula 4)

Similarly, with respect to the second contact side 172, when the amount of change in the second contact length due to the deviation of the trench 13 is defined as d3, d4, the following Formula 5 and Formula 6 are established.

ΔL/d3=tan θ3 (Formula 5)

ΔL/d4=tan θ4 (Formula 6)

Therefore, the total change amount of the second contact length is represented by the following Formula 7.

d3+d4=ΔL/tan θ3+ΔL/tan θ4 (Formula 7)

In order to restrict the sum of the first contact length and the second contact length from changing even when the trench 13 is displaced in the second direction, Formula 4 and Formula 7 maybe equal to each other, and thus Formula 8 below may be satisfied.

ΔL/tan θ1+ΔL/tan θ2=ΔL/tan θ3+ΔL/tan θ4 (Formula 8)

Formula 8 is transformed into Formula 1. Therefore, in the present embodiment, the first to fourth angles θ1 to θ4 are adjusted so as to satisfy Formula 1.

Similarly to the modifications of the first embodiment, the contact region 17 of the present embodiment may have a configuration in which the linear portion 173a connected to the first contact side 171 and the linear portion 173a connected to the second contact side 172 are connected by the linear portion 175a. The contact region 17 maybe configured such that the linear portion 173b connected to the first contact side 171 and the linear portion 173b connected to the second contact side 172 are connected by the linear portion 175b.

Even with such a configuration, the sum of the first contact length and the second contact length does not change when the trench 13 is displaced in the second direction. In the contact region 17 of the present embodiment, the first angle θ1 and the third angle θ3 are equal to each other, and the second angle θ2 and the fourth angle θ4 are equal to each other. Thus, the contact region 17 is configured so as to satisfy Formula 1. Further, in the first embodiment, since the first to fourth angles θ1 to θ4 are all equal to each other, Formula 1 is satisfied.

According to the present embodiment, the first angle θ1 and the second angle θ2 are set to be less than 90°, and the third angle θ3 and the fourth angle θ4 are set to be less than 90°. Accordingly, the same effect as that of the first embodiment can be obtained.

(1) As in the present embodiment, by forming the contact region 17 so as to satisfy Formula 1, the same effect as that of the first embodiment can be obtained. In addition, since the contact region 17 maybe formed so as to satisfy Formula 1, the shape of the contact region 17 can be easily modified compared to the first embodiment in which the first to fourth angles θ1 to θ4 are all equal to each other.

### Modification of Second Embodiment

A modification of the second embodiment will be described below. In the second embodiment, the shape of the contact region 17 can be appropriately changed while Formula 1 is satisfied. For example, as illustrated in FIG. 10, the contact region 17 is configured such that the first angle θ1 is equal to the third angle θ3, and the second angle θ2 is equal to the fourth angle θ4.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and forms, and further, other combinations and forms including only one element, or more or less than these elements are also within the sprit and the scope of the present disclosure.

In the first embodiment, the semiconductor device includes the MOSFET having the trench gate structure of the n-channel type in which the first conductivity type is the n-type and the second conductivity type is the p-type. However, this is merely an example. For example, the semiconductor device may include a MOSFET having a trench gate structure of a p-channel type in which the conductivity type of each component is inverted with respect to an n-channel type. Other than the MOSFET, the semiconductor device may include an IGBT with a similar structure. The IGBT is the same as the MOSFET described in each of the above embodiments except that the n⁺-type drain layer is changed to a p⁺-type collector layer.

What is claimed is:

1. A semiconductor device comprising:
a drift layer having a first conductivity type;
a base layer having a second conductivity type and disposed on the drift layer;
an impurity layer of the first conductivity type or the second conductivity type formed opposite to the base layer through the drift layer;
a plurality of trench gate structures, each of which having
a trench extending through the base layer and having a longitudinal direction crossing a stacking direction of the drift layer and the base layer, a gate insulating film formed on a wall surface of the trench, and a gate electrode formed on the gate insulating film;
a first impurity region of the first conductivity type formed on a surface layer portion of the base layer and having an impurity concentration higher than that of the drift layer;
a second impurity region of the second conductivity type formed on a surface layer portion of the base layer and having an impurity concentration higher than that of the base layer;
a first electrode electrically connected to the first impurity region and the second impurity region;
a second electrode electrically connected to the impurity layer, wherein the first impurity region and the second impurity region are alternately formed along the longitudinal direction of the trench, the second impurity region, which is viewed in the stacking direction of the drift layer and the base layer, has:
a first contact side in contact with a first trench in a lateral direction intersecting the longitudinal direction, the first contact side having a predetermined length and two boundaries, and a second contact side in contact with a second trench adjacent to the first trench in the lateral direction, the second contact side having a predetermined length and two boundaries,
a first linear portion is defined to extend from one of the boundaries of the first contact side toward the second trench,
a second linear portion is defined to extend from the other of the boundaries of the first contact side toward the second trench,
a third linear portion is defined to extend from one of the boundaries of the second contact side toward the first trench,
a fourth linear portion is defined to extend from the other of the boundaries of the second contact side toward the first trench,
one of a first angle between the first trench and the first linear portion and a second angle between the first trench and the second linear portion is less than 90° and the other angle is less than or equal to 90°, and
one of a third angle between the second trench and the third linear portion and a fourth angle between the second trench and the fourth linear portion is less than 90°, and the other angle is less than or equal to 90°.

2. The semiconductor device according to claim 1, wherein
the first angle and the second angle are respectively defined as θ1 and θ2,
the third angle and the fourth angle are respectively defined as θ3 and θ4, and
a formula of 1/tan θ1+1/tan θ2 =1/tan θ3+1/tan θ4 is satisfied.

3. The semiconductor device according to claim 2, wherein one of the first angle and the second angle is equal to one of the third angle and the fourth angle.
